(19) United States
(12) Patent Application Publication
(10) Pub. No.: US 2018/0110135 A1
(43) Pub. Date: Apr. 19, 2018

(54) Display and control module

(71) Applicant: VEGA GRIESHABER KG, Wolfach (DE)

(72) Inventors: Christian Sum, Wolfach (DE); Volker ALLGAIER, Haslach (DE); Holger Staiger, Hardt (DE); Karl Griessbaum, Muehlenbach (DE)

(21) Appl. No.: 15/357,410

(22) Filed: Nov. 21, 2016

(30) Foreign Application Priority Data
Oct. 18, 2016 (DE) 20 2016 105 839.2

(51) Int. Cl. H05K 5/00; H05K 5/02

(52) U.S. Cl. CPC H05K 5/0017; H05K 5/0247; H05K 5/0221

(57) ABSTRACT

A display and control module of a field device, comprising a housing, a display unit arranged in the housing which is visible from the outside, and an electronics unit, wherein an exchangeable energy storage unit is arranged in the housing for at least partially supplying energy to the display and control module, and alternate embodiments thereof.

### CROSS REFERENCE TO RELATED APPLICATIONS

This patent application claims priority to German Patent Application 20 2016 105 839.2, filed on Oct. 18, 2016.

### STATEMENT REGARDING FEDERALLY SPONSORED RESEARCH OR DEVELOPMENT

No federal government funds were used in researching or developing this invention.

### NAMES OF PARTIES TO A JOINT RESEARCH AGREEMENT

Not applicable.

### SEQUENCE LISTING INCLUDED AND INCORPORATED BY REFERENCE HEREIN

Not applicable.

### BACKGROUND

### Field of the Invention

The present invention relates to a display and control module.

### Background of the Invention

In technical process automation, field devices are frequently used, which serve to detect and/or influence process variables. Examples for such field devices are fill gauges, limit gauges, and pressure measuring devices with sensors, which detect the respective process variables fill level, limit, or pressure. Frequently such field devices are connected to superordinate units, for example guidance systems or control units. These superordinate units serve for process control, process visualization, and/or process monitoring.

The energy and/or signal transmission between the field device and the superordinate units occurs frequently according to the 4 mA to 20 mA standard of prior art, in which a 4 mA to 20 mA current circuit and/or a two-wire line is formed between the field device and the superordinate unit. In addition to the analog transmission of signals the option is given that the measuring devices transmit other information to the superordinate unit via different other protocols, particularly digital protocols, or receive such information from them. Examples to be named are here the HART-protocol or the Profibus-PA-protocol.

The energy supply of these field devices also occurs via the 4 mA to 20 mA current signal so that in addition to the two-wire line no other supply line is required. In order to keep the wiring and installation expense as well as the safety measures as low as possible, for example in applications in areas protected from explosions, it is not desired to provide additional power supply lines.

Various applications exist in prior art in which it is necessary to supply such field devices with additional energy because the energy available from the current loop is not sufficient for all operating conditions.

It is known from prior art, for example, to use radio modules for an easier operation of field devices. Solutions are known in which the field devices comprise integrated radio modules, radio modules are retrofitted or arranged in a measuring converter supply device, a device for supplying energy to field devices. In particular in variants with integrated radio modules or with a radio module to be retrofitted, it is problematic in prior art that the energy supply via the 4 mA to 20 mA current loop provides only extremely low power, and the energy that can be supplied via the current loop is sometimes insufficient to simultaneously supply the radio module, the electronic unit, and the sensor with sufficient energy so that operation is impossible or only with difficulty.

Solutions are known from prior art, for example, in which the radio module is provided with its own external energy supply. However, in this solution the additional wiring expense is considered disadvantageous.

Further, modularly designed field devices are known from prior art, in which it is selected from a plurality of sensors, housings, electronic units, and control and/or display units that can be combined, and a respective field device can be generated therefrom. Such a modular field device concept is offered for example by the company Vega Grieshaber KG. Usually, a sensor, an appropriate electronics module, which provides processing of measurements and an interface for controlling and/or perhaps provides a field bus, as well as different display and/or control units can be combined. The sensors, electronics module, and display and/or control units are adjusted to each other as well as to different available housings.

There is the need in field devices, particularly modularly designed field devices, to provide an option to supply the field device with additional energy, for example to allow reliably operating a radio module, that shows none of the disadvantages known from prior art.

The objective of the present invention is therefore to integrate an exchangeable energy storage unit in a field device.

This objective is attained in a display and operating module, a modularly designed field device, and a modular field device system, each with the features as described herein.

### BRIEF SUMMARY OF THE INVENTION

In a preferred embodiment, a display and/or control module (1) of a field device (100), comprising a housing (3), a display unit (5) arranged in the housing (3) which is visible from the outside, and an electronics unit (7), characterized in that an exchangeable energy storage unit (9) is arranged in the housing (3) for at least partially supplying energy to the display and/or control module (1).

In another preferred embodiment, the display and/or control module (1) as described herein, characterized in that the exchangeable energy storage (9) is arranged between the display unit (5) and the electronics unit (7).

In another preferred embodiment, the display and/or control module (1) as described herein, characterized in that essentially all electronic components are arranged on a side of the electronics unit (7) facing the display unit (5).

In another preferred embodiment, the display and/or control module (1) as described herein, characterized in that the electronics unit (7) comprises a seat (11) connected fixed to the electronics unit (7) for contacting the exchangeable energy storage unit (9).

In another preferred embodiment, the display and/or control module (1) as described herein, characterized in that all components of the electronics unit (7) are arranged such that a clear space is provided in an edge section for accepting a seat (11) for the exchangeable energy storage unit (9).

In another preferred embodiment, the display and/or control module (1) as described herein, characterized in that the exchangeable energy storage unit (9) is accepted in a socket (13) that can be inserted into the housing (3), preferably can be pushed into it.

In another preferred embodiment, the display and/or control module (1) as described herein, characterized in that the socket (13) comprises a loss prevention system (23) for the exchangeable energy storage unit (9).

In another preferred embodiment, the display and/or control module (1) as described herein, characterized in that the loss prevention system (23) is embodied by at least one, preferably two latching cams (17, 18) overlapping the exchangeable energy storage unit (9).

In another preferred embodiment, the display and/or control module (1) as described herein, characterized in that at least one of the latching cams (17, 18) comprises a leading edge (20, 21).

In another preferred embodiment, the display and/or control module (1) as described herein, characterized in that the socket (13) comprises mechanical safety for correct polarization (23) for the exchangeable energy storage unit (9).

In another preferred embodiment, the display and/or control module (1) as described herein, characterized in that the safety for correct polarization (23) is embodied as a circumferential support brim (23) for the energy storage unit (9) which is sized such that any insertion of the energy storage unit (9) is only possible in a predetermined alignment.

In another preferred embodiment, the display and/or control module (1) as described herein, characterized in that the socket (13) comprises a loss prevention system to prevent any unintentional removal from the housing (3).

In another preferred embodiment, the display and/or control module (1) as described herein, characterized in that the loss prevention system is embodied by two latching cams (29, 30) at two support arms (26, 27) arranged opposite each other at the socket (13), with the latching cams (29, 30) in the inserted state of the socket (13) engaging behind two correspondingly embodied pins (31, 32).

In another preferred embodiment, the display and/or control module (1) as described herein, characterized in that the pins (31, 32) and the latching cams (17, 18) show leading edges (35a, 35b) arranged corresponding to each other.

In another preferred embodiment, the display and/or control module (1) as described herein, characterized in that the socket (13) and the housing (3) show latching cams (38) and undercuts (39) embodied corresponding to each other, which latch in the completely inserted state of the socket (13) in the housing (3).

In another preferred embodiment, the display and/or control module (1) as described herein, characterized in that the exchangeable energy storage unit (9) is embodied as a coin cell.

In a separate preferred embodiment, a modularly designed field device (100) with a field device housing, a sensor, and a field device electronic arranged in the field device housing, as well as a display and/or control unit (1) that can be detachably connected to the field device electronic, characterized in that the display and/or control unit (1) is embodied as described herein.

In a separate preferred embodiment, a modular field device system with
a plurality of sensors,
a plurality of field device electronics that can be connected to the sensors, and
a plurality of display and/or control units (1) that can be connected to the field device electronics, with the field device system comprising at least one display and/or control unit (1) as described herein.

### BRIEF DESCRIPTION OF THE DRAWINGS

FIG. 1 is a line drawing evidencing a perspective view of a display and control module with an interchangeable energy storage unit.

FIG. 2 is a line drawing evidencing an axial cross-section through the display and control module of FIG. 1.

FIG. 3A is a line drawing evidencing shows a perspective view of a socket of the exchangeable energy storage unit.

FIG. 3B is a line drawing evidencing an alternate view of FIG. 3A.

FIG. 4 is a line drawing evidencing a top view of a detail of the electronics unit with a partially inserted, exchangeable energy storage unit.

FIG. 5 is a line drawing evidencing an exploded illustration of a modularly designed field device.

### DETAILED DESCRIPTION OF THE INVENTION

The invention is a display and/or control module of a field device, comprising a housing, a display unit arranged in the housing and visible from the outside, and an electronics unit, is characterized in an exchangeable energy storage unit arranged in the housing for at least partially supplying energy to the display and/or control module. The arrangement of the exchangeable energy storage unit in the display and/or control unit is particularly advantageous in modularly designed field devices with an exchangeable display and/or control unit. In this case, the display and/or control unit is embodied as a separately manipulated module. A particularly space-saving arrangement and/or integration of the exchangeable energy storage unit in the display and/or control module is possible when the exchangeable energy storage unit is arranged between the display unit and the electronics unit.

By such an arrangement an assembly can be generated in which the exterior design of the display and/or control module can remain largely unchanged. By the arrangement of the exchangeable energy storage unit between the display unit and the electronics unit additionally good connectivity options become available, in order to connect the exchangeable energy storage unit to the electronics unit and/or the display unit.

A particularly space-saving arrangement can be yielded when essentially all electronic components are arranged on the side of the electronics unit facing the display unit.

This way it is achieved that the integration of the exchangeable energy storage unit requires no additional structural height for the electronics unit and thus no additional structural height is required for the display module and/or the control module. The exchangeable energy storage unit can therefore be arranged in a clear space between the electronics unit, which is typically formed as a circuit board equipped with components, and the display unit that is necessary anyways due to the electronic components.

Advantageously the electronics unit shows a seat, connected fixed to the electronics unit, for contacting the exchangeable energy storage unit. This way, for example a conventional battery seat can be arranged on the electronics unit for contacting the exchangeable energy storage unit and the exchangeable energy storage unit can be electrically connected thereby to the electronics unit.

A space-saving arrangement, particularly without the need for additional structural space, can be yielded when all components of the electronics unit are arranged such that a clear space is provided in an edge section for arranging the seat of the exchangeable energy storage unit.

Since the seat for contacting the exchangeable energy storage unit is arranged in an edge section of the electronics unit, even in case of an arrangement of the exchangeable energy storage unit between the electronics unit and the display unit, it can be achieved that it is rendered accessible laterally from the outside, at least in the edge section, so that the exchangeability can still be ensured without major expense for disassembling.

To ensure an exchange of the exchangeable energy storage unit with little expense it may be beneficial if the exchangeable energy storage unit is seated in a socket that can be inserted in the housing, particularly pushed into it.

The socket that can be inserted and/or pushed into the housing is here preferably designed such that it keeps free electric contact sites of the exchangeable energy storage unit for contacting by the seat, i.e. that for example the poles of the exchangeable energy storage unit remain accessible for electric contacting.

It is beneficial for the user when the socket shows loss prevention for the exchangeable energy storage unit, i.e. that the exchangeable energy storage unit under normal circumstances cannot fall out of the socket by itself or that it shifts such that a correct insertion into the seat is no longer possible or that it becomes lost.

Such loss prevention can be embodied for example by at least one latching cam, preferably two latching cams overlapping the exchangeable energy storage unit. By providing respective latching cams, which overlap the exchangeable energy storage unit in a position when inserted in the socket and fixing it therein it is achieved that the exchangeable energy storage unit can be prevented from shifting or falling out of the socket.

To ensure a comfortable inserting of the exchangeable energy storage unit into the socket it may be beneficial if at least one of the latching cams shows a leading edge. Such a leading edge is here embodied preferably such that the exchangeable energy storage unit is guided during the insertion process into the socket along this leading edge into the position inserted in the socket.

In a further development, the socket additionally comprises a mechanic safety for the correct polarization of the exchangeable energy storage unit. In particular, for applications in environments to be protected from explosions, such a safety for correct polarization is mandatory in order to ensure the features of the field device that prevent explosions.

Such safety for correct polarization can be embodied in a particularly simple fashion, for example as a circumferential support brim for the energy storage unit, which is sized such that any insertion of the energy storage unit is possible only in the predetermined alignment.

If for example a coin cell is used as the exchangeable energy storage unit, the safety for correct polarization can be embodied by a circumferential brim, which follows the form of the coin cell used in the proximity of the negative terminal, and thus prevents any insertion and contacting in the wrong orientation.

In a further development of the object of the application the socket shows a loss prevention for an unintentional removal out of the housing. By such a loss prevention it can additionally be achieved that the socket cannot be unintentionally removed from the housing or falls out of it after an initial release so that even an unintentional losing or falling to the ground of the socket with the inserted, exchangeable energy storage unit is avoided.

Such a loss prevention can be formed for example by two latching hooks embodied at oppositely located support arms arranged at the socket, with the latching hook in the inserted state

of the socket engaging behind two correspondingly embodied pins.

By providing two appropriately embodied latching hooks at the above-mentioned support arms, which are preferably embodied resilient in the direction of the latching hooks, it can be achieved that the socket in a defined open position is held in the housing by the approach of the latching hooks at the pins correspondingly arranged for this purpose. By overcoming additional resistance, which results in that the latching hooks glide beyond the pins, the socket can still be removed from the housing. To ensure secure fastening of the socket in the housing in the inserted state it may be beneficial for the socket and the housing to comprise latching cams and undercuts, embodied mutually corresponding, which in the completely inserted state of the socket engage each other. In addition to the mechanic securing of the socket in the housing, by such an embodiment, additionally a tactile and acoustic signal can be provided for the user, which signalizes that the socket has been completely inserted into the housing.

In a preferred embodiment, the exchangeable energy storage unit is formed as a coin cell.

A coin cell according to the present application represents an electro-chemical cell, particularly a battery or a fuel cell, with a round cross-section and a total height that is smaller than the total diameter.

By their flat embodiment, coin cells are particularly well suited for the integration in a flat

housing and can be inserted particularly easily into the housing via a socket embodied like a drawer, and electrically contacted by a socket contacting the coin cell at the top and the bottom.

The above-described display and/or control module is preferably used in a modularly designed field device with a field device housing, a sensor, and a field device electronics arranged in the field device housing, with the display and/or control unit being embodied for a detachable connection to the field device electronics.

The advantages of the present invention have particularly positive effects if the above-described display and/or control module is a component of the modular field device system with a plurality of sensors, a plurality of field device electronics that can be connected to the sensors, and a plurality of display and/or control units that can be connected to the field device electronics, because by the space-saving integration of the exchangeable energy storage unit the exterior dimensions of the display and/or control unit can be maintained and thus a flawless integration is possible in the modular field device system.

### DETAILED DESCRIPTION OF THE FIGURES

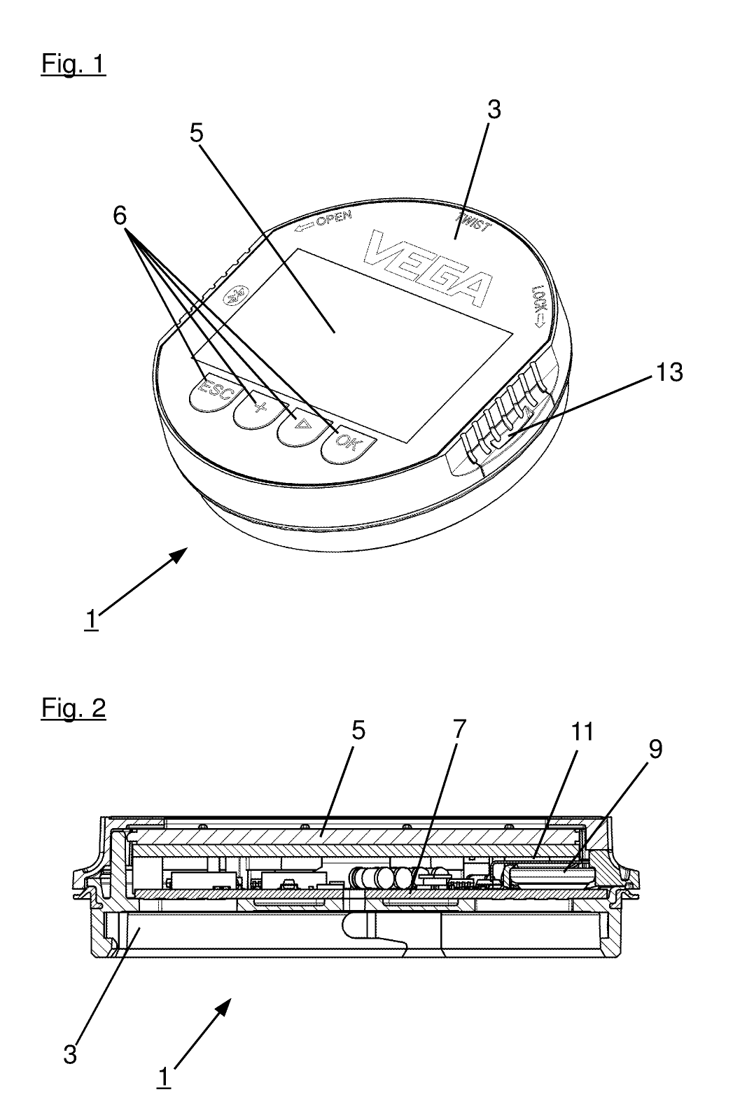

FIG. 1 shows a perspective view of a display and control module 1, according to the present invention.

The display and control module 1 comprises essentially a cylindrically embodied housing 3 made from a synthetic material, in which as shown above a display unit 5 is arranged at the top, which is visible from the outside. In order to operate a field device 100, controlled via the display and control module 1, the display and control module shows control elements 6 embodied as push buttons as well as a radio interface, not shown in greater detail here.

In the exemplary embodiment shown in FIG. 1 a socket 13 is arranged laterally at the display and control module 1, via which an exchangeable energy storage unit 9 can be inserted into the display and control module 1.

FIG. 2 shows a cross-section in the axial direction of the cylindrically embodied housing 3 of the display and control module 1.

In the cross-sectional illustration, it is clearly discernible that in the housing 3 of the display and control module 1 the display unit 5 is arranged at the top such that it can be scanned from the outside via a viewing window. An electronics unit 7 is also arranged in the housing 3 and aligned parallel in reference to the display unit 5, which in the present exemplary embodiment is embodied as a circuit board 7 equipped with electronic components. In the exemplary embodiment shown in FIG. 2 it is clearly discernible that the overwhelming part of the electronic components of the electronics unit 7 is arranged on a surface of the electronics unit 7 facing the display unit 5. In addition to the electronic components, the socket 11 is also arranged on this side of the electronics unit 7, by which the exchangeable energy storage unit 9, in the present exemplary embodiment embodied as a coin cell, is electrically contacted. Since a certain distance between the components arranged on the surface of the electronics unit 7 from the display unit 5 must be maintained, the socket 11 for the coin cell 9 can be integrated in a space-saving fashion and without requiring any additional, higher structural space.

The socket 11, as shown in FIG. 2, is arranged in an edge section of the electronics unit 7 such that the coin cell 9 can be inserted via the socket 13 laterally into the seat 11 and can here be contacted electronically.

A fastening device of the display and control module 1 is provided at a side of the housing 3 opposite the display unit 5, which in the present exemplary embodiment is embodied as a bayonet nut connector. This way the display and control module 1 can be connected very easily using simple components of the field device 100, for example of a field device electronics.

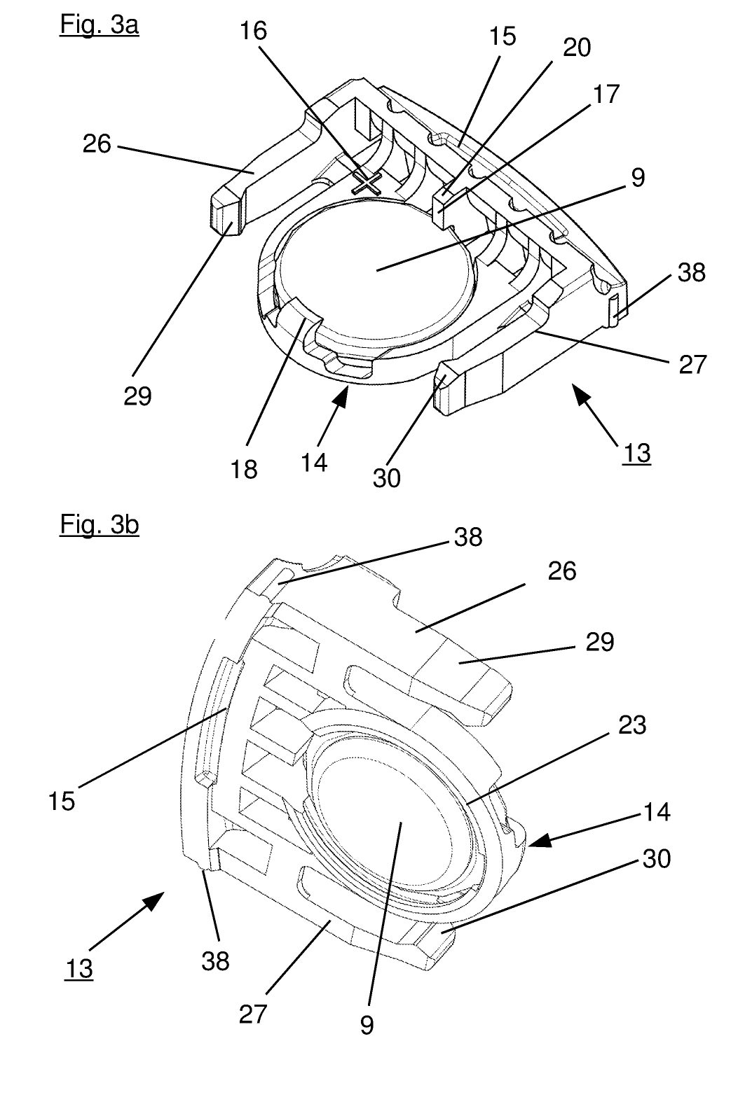

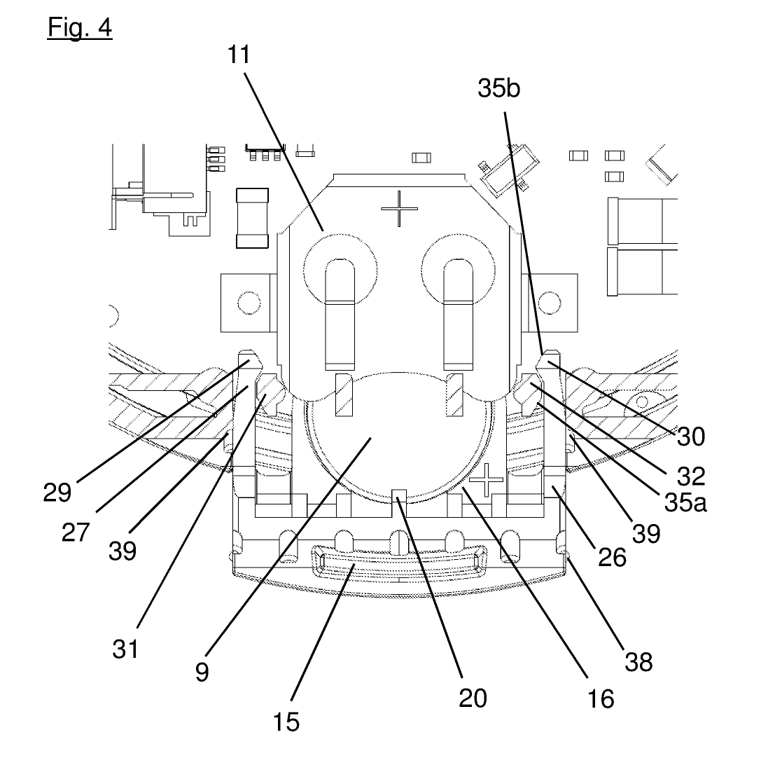

FIGS. 3a and 3b show an enlarged perspective view of the socket 13 with the coin cell 9 inserted therein.

In the present exemplary embodiment, the socket 13 is essentially embodied with the function of a drawer and serves for fastening and aligning the coin cell 9 such that it is held both exchangeably as well as reliably in the socket 11 and thus can be inserted in the housing 3. For this purpose, the socket 13 comprises a socket frame 14, which is adjusted to the exterior shape of the coin cell 9 such that the coin cell can be inserted essentially without play into the socket frame 14. In order to fasten the coin cell 9 in the socket frame 14, it shows on the one hand a support brim 23, on which the coin cell rests at its edge, and thus it is prevented from falling through the socket frame 14. In the present exemplary embodiment, the support frame 23 is simultaneously embodied as a safety for correct polarization, because it follows the exterior contour of a coin cell such that any insertion of the coin cell in the wrong orientation and/or any electric contacting of the circuit board is prevented.

To prevent the coin cell 9 from falling out of the socket frame 14, the socket 13 comprises two latching cams 17, 18, arranged opposite each other, which overlaps the coin cell in the inserted state in a latching fashion. To allow easy insertion of the coin cell 9 the latching cams 17, 18 each show leading edges 20, which ensure the insertion of the coin cell into the socket frame 14 and any gliding of the latching cams 17, 18 and subsequent latching engagement of the coin cell.

In addition to the safety for correct polarization, embodied as a support brim 23, the socket 13 additionally comprises a marking 16 by which the correct polarity for inserting the coin cell 9 is indicated.

The socket 13 is held and guided in the housing 3 via two support arms 26, 27 laterally arranged at the socket frame 14. For this purpose, the support arms 26, 27 are embodied with laterally guide areas for a non-jamming insertion of the socket 13 into the housing 3. In order to prevent that the socket 13 unintentionally falls out of the housing 3, latching hooks 29, 30 are formed at the front at the support arms 26, 27, which in the inserted state of the socket 13 engage behind pins 31, 32 embodied corresponding thereto. When opening and/or pulling the socket 13 out of the housing 3 the socket 13 is pulled out of the housing 3. Here, the latching hooks 29, 30 approaching the pins 31, 32 represent a resistance, which prevents that the socket 13 is unintentionally and completely pulled out of the housing 3. If additional force is applied, the latching hooks 29, 30 glide under elastic deformation of the support arms 26, 27 past the pins 31, 32 such that the socket 13 can be removed completely out of the housing 3. To facilitate a renewed insertion of the socket 13 into the housing 3, the support arm 26, 27 and the pins 31, 32 show leading edges 35a, 35b embodied corresponding to each other, which resiliently bend the support arms 26, 27 during the insertion of the socket 13 until the latching hooks 29, 30 latch behind the pins 31, 32.

To facilitate pulling the socket 13 out of the housing 3, it shows an engagement opening 15 in its section pointing outwardly that is accessible from the outside, in which for example without any tools, using a fingernail or a common slotted screwdriver, engagement can occur and this way the socket 13 can be pulled out of the housing 3.

In order to ensure a secure fastening of the exchangeable energy storage unit 9 including the socket 13 in the housing 3, said housing 3 and the socket 13 show latching cams 38 and undercuts 39, which are embodied corresponding to each other, which ensure in the completely inserted state of the socket 13 in the housing 3 a mechanic latching of the socket 13 to the housing 3 and provide the user during the insertion process with a feedback that can be felt and heard for the correct insertion of the socket 13 in the housing.

The integration of the coin cell 9 in the housing 3 as well as the contacting thereof by the seat 11 is particularly characterized in that a common battery seat for coin cells can be used as the seat 11. This is particularly ensured by a clever design of the socket 13, which allows contacting the coin cell 9 at the top and the bottom and ensures via the socket 13 its orientation and mechanic fastening in the housing 3.

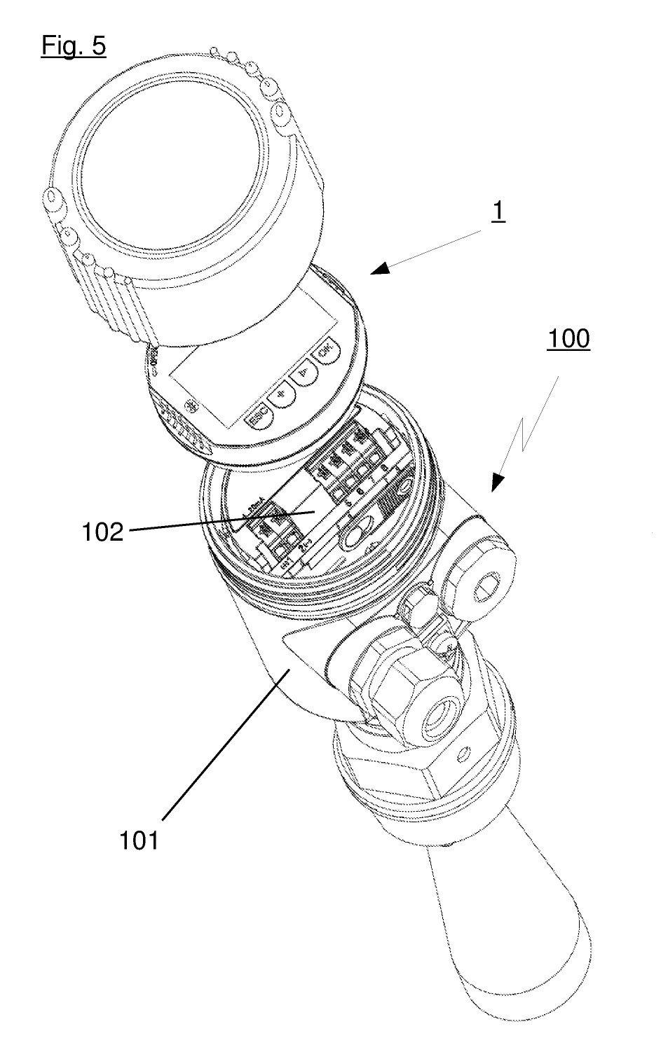

FIG. 5 shows in an exploded illustration a modularly designed field device 100. In the present case, the field device 100 is embodied as a radar fill gauge, which comprises for the process a horn antenna with a transceiver element arranged behind it. A measuring electronic 102 with electric and mechanic contacts is arranged in the field device housing 101 for the display and/or control module 1 embodied as a separately manipulated module.

The display and/or control module 1 can in the present case be fastened via a bayonet nut connector in the measuring device housing 101 and be arranged such that electric contacting occurs of the measuring device electronics 102. The control elements of the display and/or control module remains accessible from the top such that scanning the display remains possible when the cover is placed onto the measuring device housing 101. When the cover is taken off manipulation occurs via the control elements and when the measuring device housing 102 is closed via a radio interface.

### LIST OF REFERENCE NUMBERS

1 Display and/or control module

3 Housing

5 Display unit

6 Control elements

7 Electronics unit

9 Energy storage unit/coin cell

11 Seat

13 Socket

14 Socket frame

15 Engagement opening

16 Marking

17 First latching cam

18 Second latching cam

20 First leading edge

23 Safety for correct polarization/support brim

26 First support arm

27 Second support arm

29 First latching hook

30 Second latching hook

31 First pin

32 Second pin

35a Leading edges

35b Leading edges

38 Latching cams

39 Undercuts

100 Field device

The references recited herein are incorporated herein in their entirety, particularly as they relate to teaching the level of ordinary skill in this art and for any disclosure necessary for the commoner understanding of the subject matter of the claimed invention. It will be clear to a person of ordinary skill in the art that the above embodiments may be altered or that insubstantial changes may be made without departing from the scope of the invention. Accordingly, the scope of the invention is determined by the scope of the following claims and their equitable equivalents.

1. A display and control module of a field device, comprising a housing, a display unit arranged in the housing which is visible from the outside, and an electronics unit, further comprising wherein an exchangeable energy storage unit is arranged in the housing for at least partially supplying energy to a display and/or control module, wherein the exchangeable energy storage unit is accepted in a socket that can be inserted into the housing, wherein the socket comprises a loss prevention system for the exchangeable energy storage unit, and wherein the loss prevention system is embodied by at least one latching cam overlapping the exchangeable energy storage unit.

2. The display and control module according to claim 1, wherein the exchangeable energy storage is arranged between the display unit and the electronics unit.

3. The display and control module according to claim 1, wherein electronic components are arranged on a side of the electronics unit facing the display unit.

4. The display and control module according to claim 1, wherein the electronics unit comprises a seat that is connected to and is fixed to the electronics unit for contacting the exchangeable energy storage unit.

5. The display and control module according to claim 1, wherein all components of the electronics unit are arranged such that a clear space is provided in an edge section for accepting a seat for the exchangeable energy storage unit.

6. (canceled)

7. (canceled)

8. (canceled)

9. The display and control module according to claim 8, wherein at least one of the latching cams comprises a leading edge.

10. The display and control module according to claim 1, wherein a socket comprises mechanical safety for correct polarization for the exchangeable energy storage unit.

11. The display and control module according to claim 10, wherein the safety for correct polarization is embodied as a circumferential support brim for the energy storage unit which is sized such that any insertion of the energy storage unit is only possible in a predetermined alignment.

12. The display and control module according to claim 1, wherein a socket comprises a loss prevention system to prevent any unintentional removal from the housing.

13. The display and control module according to claim 12, wherein the loss prevention system is embodied by two latching cams at two support arms arranged opposite each other at the socket, with the latching cams in the inserted state of the socket engaging behind two correspondingly embodied pins.

14. The display and control module according to claim 13, wherein the pins and the latching cams comprises leading edges arranged corresponding to each other.

15. The display and control module according to claim 1, wherein a socket and the housing comprising latching cams and undercuts embodied corresponding to each other, which latch in the completely inserted state of the socket in the housing.

16. The display and control module according to claim 1, wherein the exchangeable energy storage unit is embodied as a coin cell.

17. A modularly designed field device with a field device housing, a sensor, and a field device electronic arranged in the field device housing, as well as a display and control unit that can be detachably connected to the field device electronic, wherein the display and control unit is embodied according to claim 1.

18. A modular field device system with
a plurality of sensors,
a plurality of field device electronics that can be connected to the sensors, and
a plurality of display and control units that can be connected to the field device electronics,
with the field device system comprising at least one display and control unit according to claim 1.
